(19) United States
(12) Patent Application Publication
(10) Pub. No.: US 2025/0239469 A1
(43) Pub. Date: Jul. 24, 2025

(54) PROTECTIVE FILM FORMING METHOD, PROTECTIVE FILM FORMING APPARATUS, AND SUBSTRATE TREATMENT SYSTEM

(71) Applicant: Tokyo Electron Limited, Tokyo (JP)

(72) Inventors: Takafumi HASHIMOTO, Koshi City (JP); Teppei TAKAHASHI, Yokkaichi City (JP); Akira NISHIYA, Koshi City (JP); Hiromitsu HYODO, Koshi City (JP)

(21) Appl. No.: 19/015,162

(22) Filed: Jan. 9, 2025

(30) Foreign Application Priority Data
Jan. 18, 2024 (JP) 2024-006183
Sep. 27, 2024 (JP) 2024-169012

(51) Int. Cl. H01L 21/67; B08B 3/08

(52) U.S. Cl. CPC H01L 21/67126; B08B 3/08

(57) ABSTRACT

A method for forming a protective film at a peripheral edge portion of a substrate having patterning layers on a front surface includes: (A) supplying a coating solution for forming the protective film to the front surface of the substrate from a front-surface side coater while rotating the substrate to form the protective film at the peripheral edge portion of the substrate; (B), after the (A), supplying a cleaning solution to a rear surface of the substrate from a cleaning solution supplier while rotating the substrate to clean the rear surface and a peripheral end surface of the substrate; and (C), after the (B), supplying the coating solution to the rear surface of the substrate from a rear-surface side coater while rotating the substrate to form the protective film on the rear surface and the peripheral end surface of the peripheral edge portion of the substrate.

### CROSS REFERENCE TO RELATED APPLICATIONS

This application is based upon and claims the benefit of priority of the prior Japanese Patent Application No. 2024-6183, filed in Japan on Jan. 18, 2024, and the prior Japanese Patent Application No. 2024-169012, filed in Japan on Sep. 27, 2024, the entire contents of which are incorporated herein by reference.

### TECHNICAL FIELD

This disclosure relates to a protective film forming method, a protective film forming apparatus, and a substrate treatment system.

### BACKGROUND

Japanese Patent Application No. 2018-49987 discloses a coating and developing method including a step of applying a resist containing metal to a front surface of a substrate to form a resist film and exposing the resist film, and a developing step of supplying a developing solution to the front surface of the substrate to develop the resist film. This coating and developing method further includes, before the developing step, a step of forming a protective film which prevents the developing solution from coming into contact with a peripheral edge portion of the substrate where the resist film is not formed, that is, at least a peripheral end surface and a rear surface side peripheral edge portion.

### SUMMARY

An aspect of this disclosure is a method for forming a protective film at a peripheral edge portion of a substrate having a plurality of patterning layers on a front surface, the method including: (A) supplying a coating solution for forming the protective film to the front surface of the substrate from a front-surface side coater located on the front surface side of the substrate while rotating the substrate to form the protective film at the peripheral edge portion of the substrate; (B), after the (A), supplying a cleaning solution to a rear surface of the substrate from a cleaning solution supplier located on the rear surface side of the substrate while rotating the substrate to clean the rear surface and a peripheral end surface of the substrate; and (C), after the (B), supplying the coating solution to the rear surface of the substrate from a rear-surface side coater located on the rear surface side of the substrate while rotating the substrate to form the protective film on the rear surface and the peripheral end surface of the peripheral edge portion of the substrate.

### BRIEF DESCRIPTION OF THE DRAWINGS

FIG. 1 is a view illustrating a substrate having a plurality of patterning layers.

FIG. 2 is a diagram schematically illustrating the outline of a configuration of a wafer treatment system as a substrate treatment system including a protective film forming apparatus according to a first embodiment.

FIG. 3 is an explanatory view schematically illustrating from a side the outline of a configuration of the protective film forming apparatus according to the first embodiment.

FIG. 4 is an explanatory view schematically illustrating from a plane the outline of the configuration of the protective film forming apparatus according to the first embodiment.

FIG. 5 is an explanatory view illustrating a discharge angle in a plan view of a front-surface side coating nozzle with respect to the substrate.

FIG. 6 is an explanatory view illustrating a discharge angle in a side view of the front-surface side coating nozzle with respect to the substrate.

FIG. 7 is a flowchart illustrating main steps of a treatment sequence executed by the wafer treatment system.

FIG. 8 is a perspective view illustrating the state of the surroundings of the substrate during the treatment sequence.

FIG. 9 is a partially enlarged sectional view illustrating the state of the vicinity of a peripheral portion of the substrate during the treatment sequence.

FIG. 10 is a view for explaining a protective film forming method according to a comparative embodiment.

FIG. 11 is a view illustrating another example of the numbers of arrangement and positions of a rear-surface side coating nozzle and a cleaning nozzle.

FIG. 12 is a view illustrating another example of the rear-surface side coating nozzle.

FIG. 13 is a view illustrating another example of the rear-surface side coating nozzle.

FIG. 14 is a view illustrating another example of the rear-surface side coating nozzle.

FIG. 15 is an explanatory view schematically illustrating from a side the outline of a configuration of a protective film forming apparatus according to a second embodiment.

FIG. 16 is an explanatory view schematically illustrating from a plane the outline of the configuration of the protective film forming apparatus according to the second embodiment.

### DETAILED DESCRIPTION

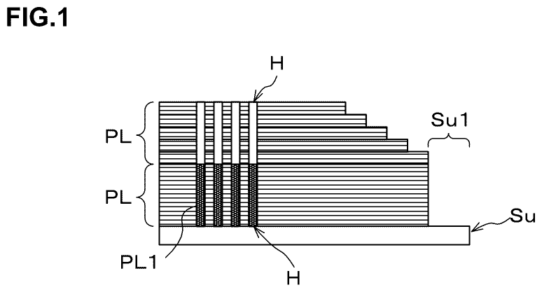

In a photolithography step in a manufacturing process of a semiconductor device in a multilayer structure such as a 3D NAND flash memory or the like, a coating treatment of supplying a coating solution onto a substrate such as a semiconductor wafer (hereinafter, referred to as a “wafer”) to form a resist film, an exposure treatment of exposing the resist film in a predetermined pattern, a developing treatment of developing the substrate after the exposure treatment to form a pattern of the resist, and so on are performed. Further, an etching treatment of the substrate using the above pattern of the resist as a mask and so on are performed to form a patterning later on the substrate. Further, until the semiconductor device in the multilayer structure is formed, a sequence of forming the patterning layer on the substrate as above is repeatedly performed a plurality of times to create a substrate Su having on a front surface a plurality of patterning layers PL as partially illustrated in FIG. 1.

Incidentally, the substrate Su having the plurality of patterning layers PL on the front surface is exposed at its peripheral edge portion Su1, and therefore may be damaged at subsequent steps on the substrate Su. For example, in the case where a base of the substrate Su having the plurality of patterning layers PL on the front surface is silicon, a peripheral edge portion Su1 of the substrate Su may be damaged at a cleaning step of removing a layer PL1, which is made of amorphous silicon being the same kind of material as silicon of the substrate Su, with a cleaning solution by a batch treatment. The layer PL1 is, specifically, a layer filling a hole H of the patterning layer PL.

Since the peripheral edge portion Su1 of the substrate Su may be damaged as above, the formation of a protective film at the peripheral edge portion Su1 is under consideration. Specifically, it is considered to supply a coating solution for forming a protective film to the substrate Su while rotating the substrate Su to form a protective film against the cleaning step on the peripheral edge portion Su1 of the substrate Su. However, the protective film cannot be appropriately formed depending on the forming method, specifically, as follows.

Specifically, a front surface of the peripheral edge portion Su1 of the substrate Su is damaged not only by the steps after the plurality of patterning layers PL are formed but also by the etching for forming the patterning layer PL, and therefore has a level difference at the formation of the protective film. If the number of rotations of the substrate Su during the formation of the protective film is decreased in order to form the protective film so as to prevent a shoulder portion of the level difference on the front surface of the peripheral edge portion Su1 from exposing, an abnormality may occur on the protective film formed on a rear surface of the peripheral edge portion Su1 of the substrate Su. Note that the damage may be accumulated on the front surface of the peripheral edge portion Su1 of the substrate Su at the cleaning step in a batch treatment and by the etching for forming the patterning layer PL, and if accumulated, there are such defects that the front surface is partially chipped to cause particles, so that the protective film is necessary. Further, if the rear surface and a peripheral end surface of the peripheral edge portion Su1 of the substrate Su are damaged by the cleaning step in the batch treatment, a damaged portion is chipped when coming into contact with a substrate treatment apparatus such as an apparatus for removing the protective film and a substrate carrier mechanism, and may become a cause of cross-contamination. Therefore, the protective film is necessary also on the rear surface and the peripheral end surface of the peripheral edge portion Su1 of the substrate Su.

Hence, the technique according to this disclosure appropriately forms a protective film at a peripheral edge portion of a substrate having a plurality of patterning layers on a front surface.

Hereinafter, configurations of a protective film forming apparatus and a substrate treatment system according to this embodiment will be explained with reference to the drawings. Note that, in this description, components having substantially the same functional configurations are denoted by the same reference signs to omit duplicate explanations.

### First Embodiment

### <Wafer Treatment System>

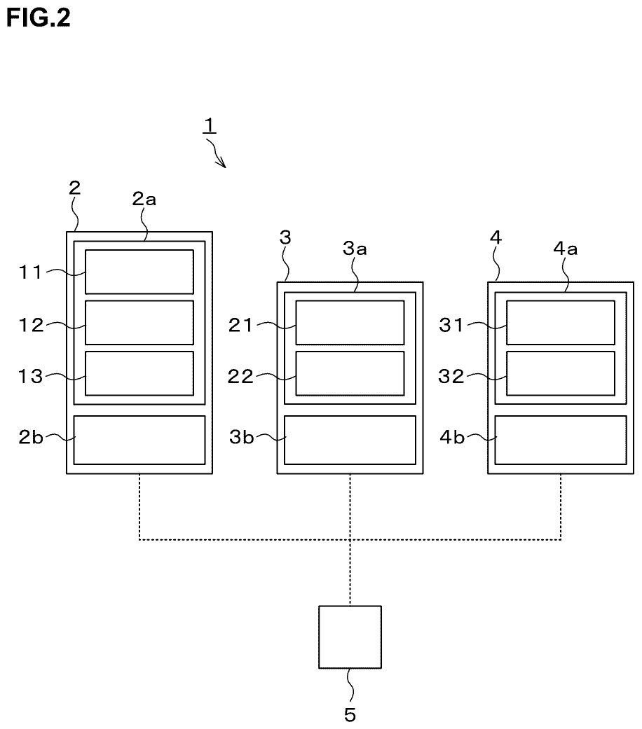

FIG. 2 is a diagram schematically illustrating the outline of a configuration of a wafer treatment system as a substrate treatment system including a protective film forming apparatus according to a first embodiment.

A wafer treatment system 1 in FIG. 2 includes a coating system 2, a cleaning system 3, and a removing system 4.

The coating system 2 has a carrier station 2a and a treatment station 2b.

To/from the carrier station 2a, wafers as substrates are carried in/out in carrier units. The carrier is a container capable of collectively housing a plurality of wafers.

The treatment station 2b has a protective film forming apparatus 11, a thermal treatment apparatus 12, and a carrier mechanism 13. Each of the protective film forming apparatus 11 and the thermal treatment apparatus 12 performs a treatment on the wafer in a single-wafer manner.

The protective film forming apparatus 11 forms a protective film at a peripheral edge portion of a wafer having a plurality of patterning layers on a front surface, like the substrate Su in FIG. 1. The above patterning layer is formed on the front surface of the wafer through a coating treatment of supplying a coating solution onto the wafer to form a resist film, an exposure treatment of exposing the resist film in a predetermined pattern, a developing treatment of developing the wafer after the exposure treatment to form a pattern of resist, and an etching treatment of the wafer using the pattern of resist as a mask. By performing the series of treatments repeatedly a plurality of times, a plurality of patterning layers are formed on the front surface of the wafer. Note that the base of the wafer is, for example, silicon. Besides, the peripheral edge portion of the wafer at which the protective film is formed by the protective film forming apparatus 11 is a region outside a device effective region on the wafer, specifically, a region outside a region of the wafer where the patterning layers are formed.

The thermal treatment apparatus 12 performs a thermal treatment such as a heat treatment or the like on the wafer on which the protective film is formed. The heat treatment by the thermal treatment apparatus 12 can vaporize a solvent contained in a coating solution for forming the protective film remaining in the protective film to harden the protective film.

The carrier mechanism 13 performs carry of the wafer in a single-wafer manner between apparatuses in the treatment station 2b and so on.

The cleaning system 3 has a carrier station 3a and a treatment station 3b.

To/from the carrier station 3a, the wafers are carried in/out in carrier units, like the carrier station 2a.

The treatment station 3b has a cleaning apparatus 21 and a carrier mechanism 22. The cleaning apparatus 21 performs treatments on the wafers by a batch treatment. In other words, the cleaning apparatus 21 performs the treatment on the wafers in lot units each composed of a plurality of wafers collected together.

The cleaning apparatus 21 specifically removes a layer made of the same kind of material as that of the base of the wafer, on which the protective film is formed, with a cleaning solution by a batch treatment. For example, in a case where the base of the wafer is silicon, the cleaning apparatus 21 removes an amorphous silicon layer (see a sign PL1 in FIG. 1), which fills a hole provided in the patterning layer of the wafer having the plurality of patterning layers on the front surface, with the cleaning solution by a batch treatment. The cleaning solution for removing the amorphous silicon layer is, for example, a choline aqueous solution (choline concentration of 4%) at 80° C.

The carrier mechanism 22 performs carry of the wafers such as carry of the wafers to the cleaning apparatus 21 in lot units in the treatment station 3b.

Note that, for example, the substrate liquid treatment system and etching treatment apparatus disclosed in Japanese Patent Application No. 2021-40162 are applicable to the cleaning system 3 and the cleaning apparatus 21.

The removing system 4 has a carrier station 4a and a treatment station 4b.

To/from the carrier station 4a, the wafers are carried in/out in carrier units, like the carrier station 2a.

The treatment station 4b has a removing apparatus 31 and a carrier mechanism 32.

The removing apparatus 31 removes the protective film from the wafer on which the protective film is formed. Specifically, the removing apparatus 31 performs removal of the protective film from the wafer in a single-wafer manner.

The carrier mechanism 32 performs carry of the wafer such as carry of the wafer to the removing apparatus 31 in a single-wafer manner in the treatment station 4b.

Note that, for example, the liquid treatment apparatus disclosed in Japanese Patent Application No. 2014-86639 is applicable to the removing apparatus 31.

Further, though the illustration is omitted, the wafer treatment system 1 includes an OHT (Overhead Hoist Transport) which performs carry of the wafers W to/from a system constituting the system 1 in carrier units.

The wafer treatment system 1 further includes at least one control device 5. The control device 5 processes a computer-executable instruction which causes the wafer treatment system 1 to execute various steps described in this disclosure. The control device 5 can be constituted to control components of the wafer treatment system 1 so as to execute the various steps described herein. In one embodiment, part or whole of the control device 5 may be included in the wafer treatment system 1. The control device 5 may include a processor, a storage, and a communication interface. The control device 5 is implemented, for example, by the computer. The processor may be configured to read a program which provides a logic or routine enabling performance of various control operations from the storage and execute the read program to perform the various control operations. This program may be stored in the storage in advance or acquired via a medium when required. The acquired program is stored in the storage, read from the storage by the processor, and executed. The medium may be various computer-readable storage media, or a communication line connected to the communication interface. The storage medium may be a transitory one or a non-transitory one. The processor may be a CPU (Central Processing Unit) or one or a plurality of circuits. The storage may include a RAM (Random Access Memory), a ROM (Read Only Memory), an HDD (Hard Dist Drive), an SDD (Solid State Drive), or a combination of them. The communication interface may communicate with the wafer treatment system 1 via the communication line such as a LAN (Local Area Network) or the like.

### <Protective Film Forming Apparatus 11>

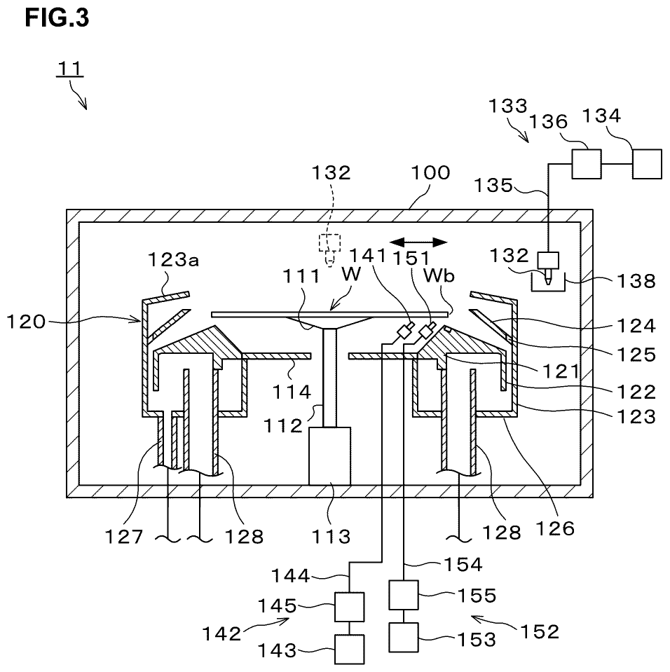

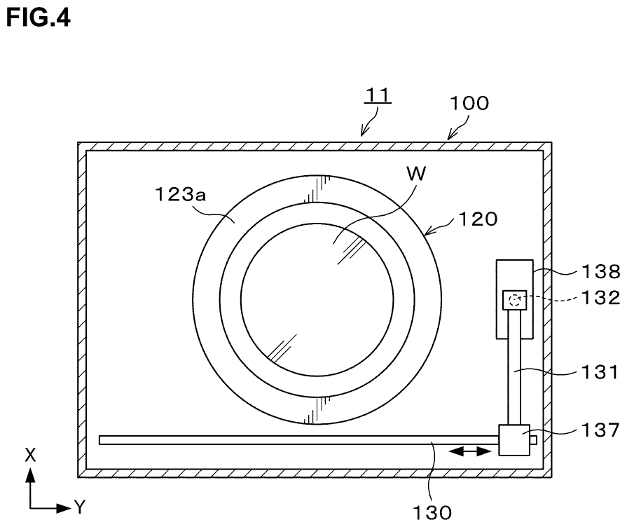

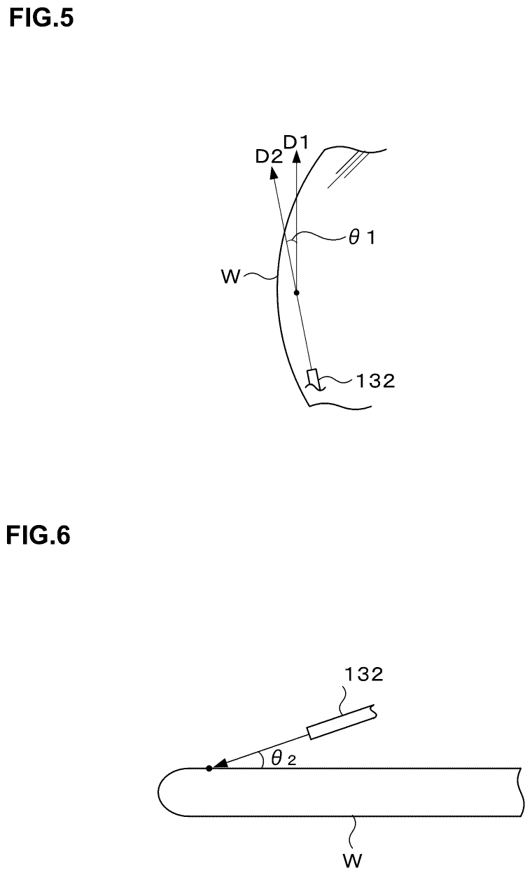

FIG. 3 is an explanatory view schematically illustrating from a side the outline of a configuration of the protective film forming apparatus 11, and FIG. 4 is an explanatory view schematically illustrating the outline from a plane. FIG. 5 and FIG. 6 are explanatory views illustrating a discharge angle in a plan view and a discharge angle in a side view of a later-explained front-surface side coating nozzle with respect to the wafer, respectively.

The protective film forming apparatus 11 is configured to form the protective film at the peripheral edge portion of the wafer having the plurality of patterning layers on the front surface as explained above. The protective film is specifically a film having resistance against the cleaning solution to be used for the treatment of removing a specific layer on the front surface of the wafer W by the cleaning apparatus 21, and more specifically an SoG film having resistance against the choline aqueous solution (choline concentration of 4%) at 80° C. As illustrated in FIG. 3 and FIG. 4, the protective film forming apparatus 11 includes a spin chuck 111 being a rotary holder which holds and rotates the wafer W, in a treatment container 100. The spin chuck 111 specifically vacuum-sucks a rear surface center portion of the wafer W to horizontally hold the wafer W and rotate the wafer W around the vertical axis,

The spin chuck 111 is connected to a chuck drive mechanism 113 via a shaft part 112. The chuck drive mechanism 113 has a rotation drive source (not illustrated) such as a motor which generates a driving force for rotating the spin chuck 111 around the vertical axis. The rotation of the spin chuck 111 by the chuck drive mechanism 113 rotates the wafer W around the vertical axis.

Further, the chuck drive mechanism 113 may be provided with a drive source such as a cylinder which generates a driving force for raising and lowering the spin chuck 111. The spin chuck 111 is raised or lowered by the chuck drive mechanism 113 to raise or lower the wafer W.

The chuck drive mechanism 113 is controlled, for example, by the control device 5.

On a lower side of the spin chuck 111, a circular plate 114 is provided in a manner to surround the shaft part 112 via a gap. The circular plate 114 is formed with through holes (not illustrated) at three or more locations along a circumferential direction, and raising and lowering pins (not illustrated) can be inserted into the through holes. These raising and lowering pins can be freely raised and lowered by a raising and lowering mechanism (not illustrated). By the raising and lowering of the raising and lowering mechanism, the raising and lowering pins can raise the wafer W released from the suction-holding by the spin chuck 111 from the top of the spin chuck 111, or lower the wafer W received from the carrier mechanism 13 to mount the wafer W on the spin chuck 111.

In the treatment container 100, a cup 120 is provided so as to surround the periphery of the wafer W held on the spin chuck 111. The cup 120 receives a treatment solution (for example, a coating solution for forming the protective film) shaken off or dropped from the wafer W held on the spin chuck 111 and guides the treatment solution to drain it to the outside.

In more detail, the cup 120 has a mountain-shaped guide part 121, which is provided in a ring shape with a mountain-shaped cross-sectional profile, around the circular plate 114, and has an annular vertical wall 122 provided in a manner to extend downward from an outer peripheral edge of the mountain-shaped guide part 121. The mountain-shaped guide part 121 guides the treatment solution dropped from the wafer W to below on the outside of the wafer W.

Further, the cup 120 has a cylindrical part 123 that is vertical to surround the mountain-shaped guide part 121 and an upper guide part 124 that diagonally extends inward and upward from a portion of the cylindrical part 123 above a vertical wall 122, on the outside of the mountain-shaped guide part 121. The upper guide part 124 is provided with a plurality of openings 125 in the circumferential direction. Further, an upper end portion of the cylindrical part 123 extends to above the spin chuck 111, and its end inner edge is provided with an inclined body 123a extending inward and upward.

The cylindrical part 123 forms at its lower side a ring-shaped liquid receiver 126 having a cross-section in a recessed shape under the mountain-shaped guide part 121 and the cylindrical part 123. To an outer peripheral side of the liquid receiver 126, a drainage path 127 is connected. Further, on an inner peripheral side of the drainage path 127 at the liquid receiver 126, two exhaust pipes 128 are provided.

Further, as illustrated in FIG. 4, a rail 130 extending along a Y-direction (right-left direction in FIG. 4) is formed on an X-direction negative direction (lower direction in FIG. 4) side of the cup 120. The rail 130 is located from a Y-direction negative direction (left direction in FIG. 4) side outer position to a Y-direction positive direction (right direction in FIG. 4) side outer position of the cup 120. On the rail 130, an arm 131 is provided to be movable along the rail 130.

On the arm 131, a front-surface side coating nozzle 132 as a front-surface side coater is supported. The front-surface side coater is configured to supply protective liquid (specifically, for example, a material of the SoG film, namely, an SoG material) that is a coating solution for forming the protective film to the front surface of the wafer W from the front surface side of the wafer W held on the spin chuck 111. A plurality of front-surface side coating nozzles 132 may be provided for one arm 131. In this case, the front-surface side coating nozzle 132 is provided, for example, for each kind of the protective liquid or each concentration of the protective liquid.

The front-surface side coating nozzle 132 is connected to a supply mechanism 133 of the protective liquid. The supply mechanism 133 has, for example, a supply pipe 135 whose one end is connected to a supply source 134 of the protective liquid. The supply pipe 135 is provided with a supply equipment group 136 for controlling the supply of the protective liquid from the supply source 134. The supply equipment group 136 has, for example, a supply valve for switching between the supply and supply stop of the protective liquid and a flow rate regulating valve for regulating the flow rate of the protective liquid.

The supply equipment group 136 is controlled, for example, by the control device 5.

The arm 131 is movable along the Y-direction on the rail 130 by a nozzle drive 137. Thus, the front-surface side coating nozzle 132 can move from a waiting section 138 provided on the Y-direction positive direction outer side of the cup 120 to above the peripheral edge portion of the wafer W held on the spin chuck 111 in the cup 120. Further, the arm 131 can rise and lower by the nozzle drive 137, whereby the height of the front-surface side coating nozzle 132 can be adjusted. The nozzle drive 137 has, for example, a motor, a cylinder, and so on as a drive source for generating a driving force for moving of the arm 131 along the rail 130 and driving the raising and lowering of the arm 131.

Besides, as illustrated in FIG. 5, a discharge angle θ1 of the front-surface side coating nozzle 132 in a plan view with respect to the wafer W is set to be an acute angle, specifically, set to an acute angle of 10° or more, and more specifically set to, for example, 25° to 45°. The discharge angle θ1 is, specifically, an angle formed between a rotation direction D1 of the wafer W at a landing point WI of the protective liquid from the front-surface side coating nozzle 132 onto the wafer W and a discharge direction D2 in a plan view of the protective liquid from the front-surface side coating nozzle 132.

By setting the discharge angle θ1 of the front-surface side coating nozzle 13 in a plan view with respect to the wafer W as above, the protective liquid discharged from the front-surface side coating nozzle 132 is less likely to move to the inner side after reaching the front surface of the wafer W, thereby making the position on an inner peripheral edge of the protective film on the front surface side of the wafer W constant in the circumferential direction of the wafer W.

Further, by setting the discharge angle θ1 of the front-surface side coating nozzle 132 in a plan view with respect to the wafer W as above, the following effects are provided. Specifically, in the case where a plurality of nozzles are provided on the arm 131, it is possible to prevent another nozzle from the front-surface side coating nozzle 132 provided on the arm 131 from being contaminated with the protective liquid discharged from the front-surface side coating nozzle 132 and bounced from the front surface of the wafer W.

Note that the front-surface side coating nozzle 132 is provided in a manner to discharge the protective liquid diagonally downward from the inside to the outside of the wafer W so that the protective liquid landed on the wafer W from the front-surface side coating nozzle 132 is directed to the outside of the wafer W. For example, a discharge angle (namely, a depression angle of the front-surface side coating nozzle 132) θ2 in a side view of the front-surface side coating nozzle 132 with respect to the wafer W is set to 15° to 35°. This can weaken the collision force of the protective liquid from the front-surface side coating nozzle 132 on the wafer W.

Returning again to FIG. 3 for explanation, a cleaning nozzle 141 as a cleaning solution supplier is arranged on the inner peripheral side of the mountain-shaped guide part 121. The cleaning solution supplier is configured to supply the cleaning solution to the rear surface of the wafer W from the rear surface side of the wafer W held on the spin chuck 111. The cleaning solution is a solvent capable of dissolving the protective liquid. Examples of the cleaning solution include a mixed solution (a mixture ratio of 7:3) of propylene glycol monomethyl ether (PGME) and propylene glycol monomethyl ether acetate (PGMEA), and cyclohexane.

The cleaning nozzle 141 is fixed, unlike the front-surface side coating nozzle 132. The cleaning nozzle 141 is connected to a supply mechanism 142 for the cleaning solution. The supply mechanism 142 has, for example, a supply pipe 144 whose one end is connected to a supply source 143 of the cleaning solution. The supply pipe 144 is provided with a supply equipment group 145 for controlling the supply of the cleaning solution from the supply source 143. The supply equipment group 145 has, for example, a supply valve for switching between the supply and supply stop of the cleaning solution and a flow rate regulating valve for regulating the flow rate of the cleaning solution.

The supply equipment group 145 is controlled, for example, by the control device 5.

Further, a rear-surface side coating nozzle 151 as a rear-surface side coater is arranged on the outside of the cleaning nozzle 141 on the inner peripheral side of the mountain-shaped guide part 121. The rear-surface side coater is configured to supply the protective liquid to the rear surface of the wafer W from the rear surface side of the wafer W held on the spin chuck 111. The protective liquids to be supplied from the rear-surface side coating nozzle 151 and the front-surface side coating nozzle 132 are the same.

The rear-surface side coating nozzle 151 is fixed, like the cleaning nozzle 141. The rear-surface side coating nozzle 151 is connected to a supply mechanism 152 for the protective liquid. The supply mechanism 152 has, for example, a supply pipe 154 whose one end is connected to a supply source 153 of the protective liquid. The supply pipe 154 is provided with a supply equipment group 155 for controlling the supply of the protective liquid from the supply source 153. The supply equipment group 155 has, for example, a supply valve for switching between the supply and supply stop of the protective liquid and a flow rate regulating valve for regulating the flow rate of the protective liquid.

The supply equipment group 155 is controlled, for example, by the control device 5.

Note that the discharge angle in a plan view with respect to the wafer W of at least one of the cleaning nozzle 141 and the rear-surface side coating nozzle 151 may be the same as that of the front-surface side coating nozzle 132.

Further, the discharge angle in a side view with respect to the wafer W of at least one of the cleaning nozzle 141 and the rear-surface side coating nozzle 151 may be the same as that of the front-surface side coating nozzle 132.

### <Example of a Treatment Sequence>

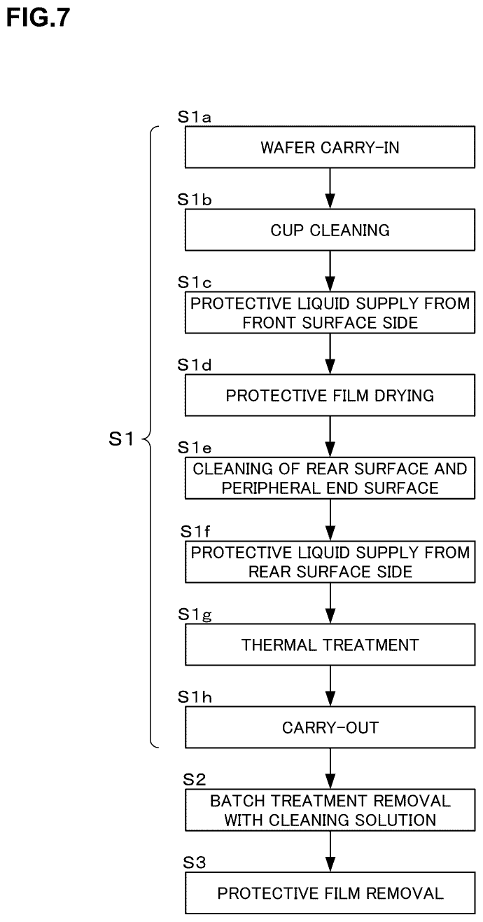

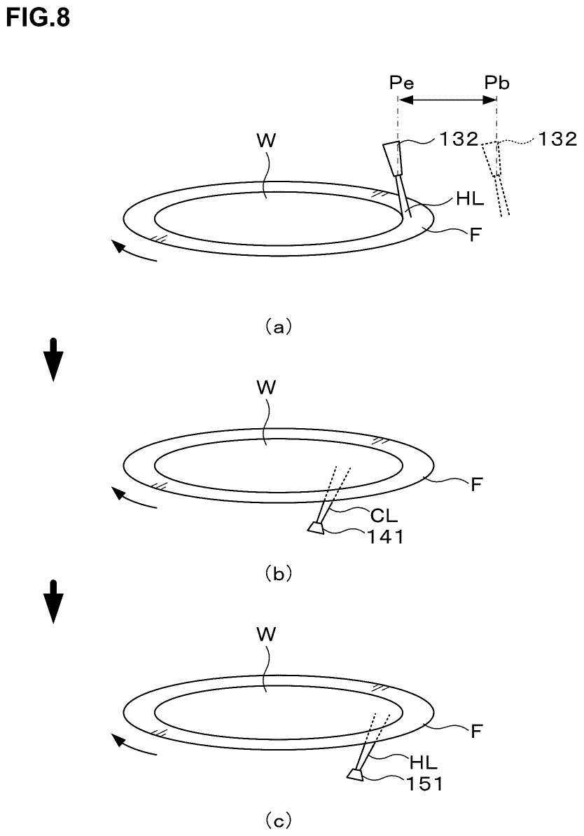

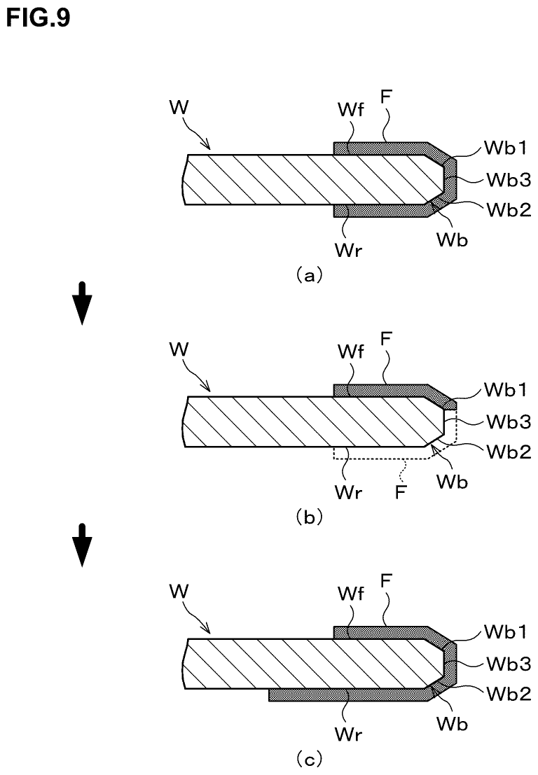

Next, an example of the treatment sequence executed by the wafer treatment system 1 will be explained using FIG. 7 to FIG. 9. FIG. 7 is a flowchart illustrating main steps of the treatment sequence executed by the wafer treatment system 1. FIG. 8 is a perspective view illustrating the state of the surroundings of the wafer W during the treatment sequence. FIG. 9 is a partially enlarged sectional view illustrating the state of the vicinity of a peripheral portion of the wafer W during the treatment sequence.

### (Step S1: Protective Film Formation)

As illustrated in FIG. 7, first, a protective film is formed at the peripheral edge portion of a wafer W having a plurality of patterning layers by the coating system 2.

This Step S1 includes, for example, the following Steps S1a to S1h.

### (Step S1a: Carry-In of the Wafer W)

At Step S1a, the wafer W is carried into the coating system 2, specifically, carried into the protective film forming apparatus 11.

More specifically, a carrier housing a plurality of wafers W is carried into the carrier station 2a of the coating system 2. Then, the wafer W in the carrier is carried into the treatment container 100 of the protective film forming apparatus 11 in the treatment station 2b via the carrier mechanism 13 and mounted on the spin chuck 111. The mounted wafer W is suction-held on the spin chuck 111.

### (Step S1b: Cup Cleaning)

At Step S1b, the wafer W is rotated, and the cleaning solution is supplied to the rear surface of the wafer W from the cleaning nozzle 141 located on the rear surface side of the wafer W to clean the cup 120.

Specifically, the wafer W held on the spin chuck 111 is rotated at a predetermined number of rotations, and the cleaning solution is supplied toward the rear surface of the wafer W from the cleaning nozzle 141. This can clean the cup 120 with the cleaning solution scattering from the rear surface of the wafer W. Further, this can also clean the rear surface of the wafer W.

Note that the cup cleaning at Step S1b may be omitted.

(Step S1c: Protective Liquid Supply from the Front Surface Side)

At Step S1c, the wafer W is rotated, and the protective liquid is supplied to the front surface of the wafer W from the front-surface side coating nozzle 132 located on the front surface side of the wafer W to form a protective film at the peripheral edge portion of the wafer W.

Specifically, for example, as illustrated in, FIG. 8(a), the front-surface side coating nozzle 132 is moved to a discharge start position Pb on the outside of the peripheral edge of the wafer W, then the discharge of protective liquid HL from the front-surface side coating nozzle 132 is started, and the wafer W held on the spin chuck 111 is rotated at a predetermined number of rotations ω1. Then, with the discharge of the protective liquid HL and the rotation of the wafer W continued, the front-surface side coating nozzle 132 is moved from the discharge start position Pb to a turnaround position Pe above the peripheral edge portion of the wafer W and then returned back to the discharge start position Pb.

By this Step S1c, as illustrated in FIG. 9(a), a protective film F is formed at the peripheral edge portion of the wafer W including a bevel portion Wb. The bevel portion Wb is composed of an inclined portion Wb1 on the front surface side, an inclined portion Wb2 on the rear surface side, and a side end surface (namely, a peripheral end surface) Wb3. This Step S1 specifically forms the protective film F in a manner to cover all of a front-surface side horizontal surface Wf, a rear-surface side horizontal surface Wr, the inclined portion Wb1 on the front surface side, the inclined portion Wb2 on the rear surface side, and the side end surface Wb3 of the peripheral edge portion of the wafer W.

The number of rotations ω1 of the wafer W at this Step S1c is lower than the number of rotations of the wafer W at Step S1e (cleaning of the rear surface and the peripheral edge surface) and Step S1f (protective liquid supply from the rear surface side) and is, for example, 50 rpm to 500 rpm, preferably 150 rpm to 200 rpm. Setting the number of rotations ω1 low as above makes it possible that even if a level difference occurs at the formation of the patterning layer on the front surface side at the peripheral edge portion of the wafer W, the protective film F can cover a shoulder portion of the level different.

Further, at this Step S1c, the front-surface side coating nozzle 132 is moved only to the outside of a protective film forming position set for the front surface side of the wafer W. This can prevent the protective liquid from the front-surface side coating nozzle 132 from reaching a region inside the set protective film forming position on the front surface of the wafer W. Specifically, at this Step S1c, since the number of rotations of the wafer W is low as explained above, the centrifugal force acting on the protective liquid on the wafer W is weak and the protective liquid from the front-surface side coating nozzle 132 is likely to move to the inside, so that the limitation of the movement position of the front-surface side coating nozzle 132 to the inside as explained above is effective.

Note that on the front surface of the wafer W, the protective film forming position is set outside the region where the patterning layer is to be formed.

The discharge time of the protective liquid HL from the front-surface side coating nozzle 132 and the moving speed of the front-surface side coating nozzle 132 at Step S1c are set to be, for example, constant irrespective of the formation width of the protective film. This can facilitate the setting of the treatment condition of the protective film formation. Note that in the constant setting as above, for example, increasing the discharge time at the discharge start position Pb makes it possible to decrease the supply time of the protective liquid to the peripheral edge portion of the wafer W to narrow the formation width of the protective film. On the other hand, decreasing the discharge time at the discharge start position Pb makes it possible to increase the supply time of the protective liquid to the peripheral edge portion of the wafer W to widen the formation width of the protective film.

### (Step S1d: Protective Film Drying)

At Step S1d, with the protective liquid not being supplied to the wafer W, the wafer W is rotated to dry the protective film F formed at Step S1c.

Specifically, with the protective liquid and the cleaning solution not being supplied to the wafer W, the wafer W held on the spin chuck 111 is rotated over a predetermined time.

At this Step S1d, the number of rotations of the wafer W may be increased over time.

Specifically, the number of rotations of the wafer W may be increased in stages. More specifically, for example, the number of rotations of the wafer W may be increased from 150 rpm to 200 rpm to 1500 rpm by 100 rpm every few seconds.

Further, the number of rotations of the wafer W may be increased at a relatively low constant acceleration (for example, 100 rpm/s).

Adjusting the number of rotations as above makes it possible to dry the protective film F while keeping the thickness of the protective film F, in particular, the thickness of the protective film F covering the front surface side of the peripheral edge portion of the wafer W. In other words, it is possible to prevent the level difference formed on the front surface side of the peripheral edge portion of the wafer W from exposing from the protective film F at this Step S1.

Note that at this Step S1d, the wafer W may be rotated at a high number of rotations (for example, 1500 rpm) for a short time after the rotation at a low number of rotations (for example, 150 rpm to 200 rpm) for a long time. This can also dry the protective film F while keeping its thickness.

### (Step S1e: Cleaning of the Rear Surface and the Peripheral End Surface)

At Step S1e, the wafer W on which the protective film F is formed is rotated, and the cleaning solution is supplied from the cleaning nozzle 141 located on the rear surface side of the wafer W to the rear surface side of the wafer W to clean the rear surface and the peripheral end surface of the wafer W.

Specifically, the wafer W held on the spin chuck 111 is rotated at a predetermined number of rotations ω2, and a cleaning solution CL is supplied from the cleaning nozzle 141 toward the rear surface of the wafer W as illustrated in FIG. 8(b). This removes the whole portion covering the rear-surface side horizontal surface Wr, the inclined portion Wb2 on the rear surface side, and the side end surface Wb3 of the peripheral edge portion of the wafer W of the protective film F as illustrated in FIG. 9(b). Further, in a case where a droplet of the protective liquid supplied to the front surface of the wafer W and a mass of the protective liquid adhere to the rear surface of the wafer W at the above Step S1c, the cleaning solution supplied at this Step S1e removes also the droplet and mass of the protective liquid. Note that the reason why a portion of the protective film F covering the inclined portion Wb1 on the front surface side of the wafer W is not removed by this Step S1e is that it is difficult to cover the whole inclined portion Wb1 on the front surface side of the wafer W with the protective film F by the following Step S1f. However, in a case where it is possible to cover a lower portion of the inclined portion Wb1 on the front surface side of the wafer W by the protective film F at the following Step S1f, a lower portion of the portion of the protective film F covering the inclined portion Wb1 on the front surface side of the wafer W may be removed by this Step S1e.

The number of rotations ω2 of the wafer W at this Step S1e is higher than the numbers of rotations of the wafer W at Step S1c (protective liquid supply from the front surface side) and Step S1f (protective liquid supply from the rear surface side) and is, for example, 2000 rpm or more, specifically, 2000 rpm. Increasing the number of rotations ω2 as above makes it possible to prevent a portion formed thick of the protective film F covering the front-surface side horizontal surface Wf of the peripheral edge portion of the wafer W from being removed with the cleaning solution.

After this Step S1e and before Step S1f (protective liquid supply from the rear surface side), a step of rotating the wafer W with the cleaning solution not being supplied to the wafer W to remove the cleaning solution to dry the wafer W may be performed.

(Step S1f: Protective Liquid Supply from the Rear Surface Side)

At Step S1f, the wafer W is rotated, and the protective liquid is supplied to the rear surface of the wafer W from the rear-surface side coating nozzle 151 located on the rear surface side of the wafer W to form a protective film F at the rear surface and the peripheral end surface of the peripheral edge portion of the wafer W.

Specifically, the wafer W held on the spin chuck 111 is rotated at a predetermined number of rotations ω3, and the protective liquid HL is supplied from the rear-surface side coating nozzle 151 toward the rear surface of the wafer Was illustrated in FIG. 8(c). Thus, a protective film F is formed at least a portion exposing from the protective film F at Step S1e at the peripheral edge portion of the wafer W as illustrated in FIG. 9(c). Specifically, this Step S1f forms the protective film F in a manner to cover all of the rear-surface side horizontal surface Wr, the inclined portion Wb2 on the rear surface side, and the side end surface Wb3 of the peripheral edge portion of the wafer W.

A position where the rear-surface side coating nozzle 151 supplies the protective liquid at this Step S1f on the rear surface of the wafer W is outside a position where the cleaning nozzle 141 supplies the cleaning solution at Step S1e on the rear surface of the wafer W. More specifically, on the rear surface of the wafer W, the position where the cleaning solution is supplied is inside the position where the protective liquid is supplied. Accordingly, a region where the protective film is to be formed on the rear surface of the wafer W is surely cleaned with the cleaning solution.

Further, the number of rotations ω3 of the wafer W at this Step S1f is higher than the number of rotation ω1 of the wafer W at Step S1c (protective liquid supply from the front surface side) and lower than the number of rotation ω2 of the wafer W at Step S1e (cleaning of the rear surface and the peripheral end surface) and is, for example, 750 rpm to 1750 rpm, preferably, 1250 to 1500 rpm. According to repeated examinations by the present inventors, setting the number of rotations ω3 to 1750 rpm or lower makes it possible to form the protective film F up to the aforementioned position at the peripheral edge portion of the wafer W. Besides, setting the number of rotations ω3 to 750 rpm or higher makes it possible to make the position of the inner peripheral edge of the protective film F on the rear surface of the wafer W constant in the circumferential direction.

After this Step S1f and before Step S1g (thermal treatment), a step of rotating the wafer W with the protective liquid not being supplied to the wafer W, to dry the protective film F formed at Step S1f may be performed.

### (Step S1g: Thermal Treatment)

After Step S1f, a heat treatment is performed on the wafer W.

Specifically, the wafer W is carried by the carrier mechanism 13 from the protective film forming apparatus 11 to the thermal treatment apparatus 12 in the treatment station 2b. Thereafter, the heat treatment is performed on the wafer W by the thermal treatment apparatus 12 to harden the protective film on the wafer W.

### (Step S1h: Carry-Out of the Wafer W)

At Step S1h, the wafer W is carried out of the coating system 2.

Specifically, the wafer W is returned from the thermal treatment apparatus 12 in the treatment station 2b to the original carrier in the carrier station 2a via the carrier mechanism 13 and so on.

Step S1 including Step S1a to Step S1h is performed on all of the wafers W in the carrier.

(Step S2: Batch Treatment Removal with the Cleaning Solution)

After Step S1, a layer made of the same kind of material as the base of the wafer W on the wafer W on which the protective film is formed is removed by a batch treatment with the cleaning solution by the cleaning system 3.

Specifically, the carrier housing the wafers W on each of which the protective film is formed is carried into the carrier station 3a of the cleaning system 3. Next, the wafers W in the carrier are carried in lot units into the cleaning apparatus 21 of the treatment station 3b via the carrier mechanism 22 and so on. Then, in the cleaning apparatus 21, the amorphous silicon layers (see a sign PL1 in FIG. 1) on the wafers W are removed with the cleaning solution in lot units. Thereafter, the wafers W are returned to the original carrier in the carrier station 3a via the carrier mechanism 22 and so on.

Step S2 is performed on all of the wafers W in the carrier.

### (Step S3: Protective Film Removal)

After Step S2, the protective film F is removed by the removing system 4 from the wafer W on which the protective film F is formed.

Specifically, the carrier housing the wafers W after Step S2 is carried into the carrier station 4a in the removing system 4. Next, the wafer W in the carrier is carried into the removing apparatus 31 in the treatment station 4b via the carrier mechanism 32 and so on. Then, the protective film F is removed from the peripheral edge portion of the wafer W in the removing apparatus 31. Thereafter, the wafer W is returned to the original carrier in the carrier station 4a via the carrier mechanism 32 and so on.

Step S3 is performed on all of the wafers W in the carrier.

With the above, the treatment sequence in this example is completed.

### Main Operations and Effects of the Embodiment

The protective film forming method according to this embodiment includes Step S1c (first protective film forming step) of supplying the protective liquid to the front surface of the wafer W from the front-surface side coating nozzle 132 located on the front surface side of the wafer W while rotating the wafer W to form a protective film at the peripheral edge portion of the wafer W as explained above. The protective film forming method according to this embodiment further includes, after Step S1c (first protective film forming step), Step S1e (cleaning step) of supplying the cleaning solution to the rear surface of the wafer W from the cleaning nozzle 141 located on the rear surface side of the wafer W while rotating of the wafer W to clean the rear surface and the peripheral end surface of the wafer W. The protective film forming method according to this embodiment furthermore includes, after Step S1e (cleaning step), Step S1f (second protective film forming step) of supplying the protective liquid to the rear surface of the wafer W from the rear-surface side coating nozzle 151 located on the rear surface side of the wafer W while rotating of the wafer W to form a protective film on the rear surface and the peripheral end surface of the peripheral edge portion of the wafer W.

As a protective film forming method different from the protective film forming method according to this embodiment (hereinafter, a protective film forming method according to a comparative embodiment), there is a method including following Step X1 and Step X2.

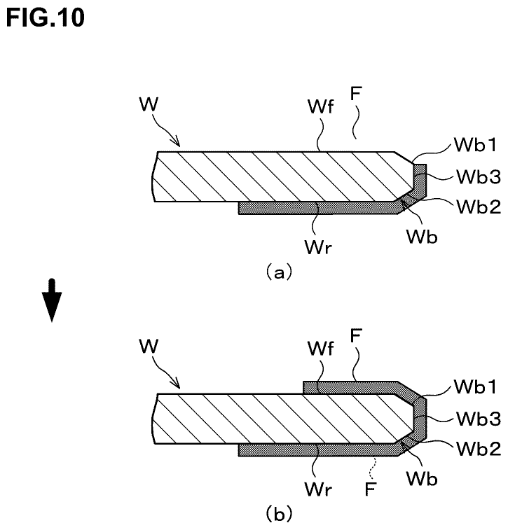

Step X1 is a step of supplying the protective liquid to the rear surface of the wafer W from the rear-surface side coating nozzle 151 located on the rear surface side of the wafer W while rotating the wafer W to form a protective film from the rear surface to the side end surface of the peripheral edge portion of the wafer W. This step forms the protective film F in a manner to cover all of the rear-surface side horizontal surface Wr, the inclined portion Wb2 on the rear surface side, and the side end surface Wb3 of the peripheral edge portion of the wafer W as illustrated, for example, in FIG. 10(a).

Step X2 is a step of, after Step X1, supplying the protective liquid to the front surface of the wafer W from the front-surface side coating nozzle 132 located on the front surface side of the wafer W while rotating the wafer W to form a protective film on the front surface side of the peripheral edge portion of the wafer W. This step forms the protective film F in a manner to cover all of the front-surface side horizontal surface Wf and the inclined portion Wb1 on the front surface side of the peripheral edge portion of the wafer W which are not covered at Step X1 as illustrated, for example, in FIG. 10(b).

In the case where a level difference is formed on the front surface of the peripheral edge portion of the wafer W, the number of rotations of the wafer W needs to be decreased at Step S1c (first protective film forming step) of the protective film forming method according to this embodiment and at Step X2 of the protective film forming method according to the comparative embodiment.

Then, if the number of rotations of the wafer W is decreased at Step X2 of the protective film forming method according to the comparative embodiment, coating failure of the protective film may occur on the rear surface of the wafer W. For example, projection due to the mass of the protective liquid may occur in the protective film on the rear surface of the peripheral edge portion of the wafer W or the droplet of the protective liquid may adhere to the protective film near a notch (not illustrated) on the rear surface of the peripheral edge portion of the wafer W.

In contrast to the above, in the protective film forming method according to this embodiment, even if the number of rotations of the wafer W is decreased at Step S1c (first protective film forming step) and the droplet and mass of the protective liquid adhere to the rear surface of the peripheral edge portion of the wafer W, Step S1e (cleaning step) can remove them. Then, Step S1f (second protective film forming step) after Step S1e (cleaning step) can newly form a protective film on the rear surface and so on of the peripheral edge portion of the wafer W. Therefore, the coating failure of the protective film on the rear surface of the wafer W as in the protective film forming method according to the comparative embodiment never occurs. In other words, according to this embodiment, it is possible to appropriately form the protective film at the peripheral edge portion of the wafer W.

Note that as another method of forming the protective film at the peripheral edge portion of the wafer W is a method by the CVD method. However, in the case of forming the protective film at the peripheral edge portion of the wafer W by the CVD method, it is difficult to fill the recess constituting the level difference on the front surface of the peripheral edge portion, and the formation itself of the protective film on the rear surface of the peripheral edge is difficult.

Besides, in the protective film forming method according to this embodiment, the plurality of patterning layers have already been formed at the time when forming the protective film at the peripheral edge portion of the wafer W. Accordingly, the protective film never affects the formation of the patterning layer, unlike at the time when forming a plurality of patterning layers after the formation of the protective film. This also applies to the case where the protective film is thick.

Incidentally, in the case of supplying the protective liquid from the front surface side of the wafer W to form the protective film as at Step S1c (first protective film forming step) in the protective film forming method according to this embodiment and Step X2 in the protective film forming method according to the comparative embodiment, the portion covering the inclined portion Wb2 on the rear surface side of the wafer W of the protective film is likely to be thicker than the other portion due to the gravity or the like. Particularly, in the protective film forming method according to the comparative embodiment, the protective film is formed in a manner to cover the inclined portion Wb2 on the rear surface side of the wafer W at Step X1 and then the protective liquid supplied from the front surface side of the wafer W at Step X2 is supplied to the inclined portion Wb2, so that a portion of the protective film covering the inclined portion Wb2 on the rear surface side of the wafer W becomes thick. If the protective film becomes too thick, the thick portion of the protective film may separate from the wafer W (namely, film lifting) or crack may occur at the thick portion of the protective film during the heat treatment after the protective film formation. In the protective film forming method according to the comparative embodiment, the portion of the protective film covering the inclined portion Wb2 on the rear surface side of the wafer W remains thick. In contrast to this, even if the portion of the protective film covering the inclined portion Wb2 on the rear surface side of the wafer W becomes thick at Step S1c (first protective film forming step) of the protective film forming method according to this embodiment, this portion is once removed at Step S1e (cleaning step). Then, at subsequent Step S1f (second protective film forming step), a protective film covering the inclined portion Wb2 on the rear surface side of the wafer W is formed by the supply of the protective liquid to the rear surface of the wafer W. Therefore, it is possible to prevent the portion of the protective film covering the inclined portion Wb2 on the rear surface side of the wafer W from becoming thick.

According to the examinations by the present inventors, in the protective film forming method according to the comparative embodiment, the portion of the protective film covering the inclined portion Wb2 on the rear surface side of the wafer W became about 2.5 times to 5 times thicker than the other portions. In contrast to this, in the protective film forming method according to this embodiment, it is possible to make the portion of the protective film covering the inclined portion Wb2 on the rear surface side of the wafer W almost the same as or thinner than the other portions.

Further, in this embodiment, the cup cleaning step at Step S1b may be omitted. Also in this case, it is possible to clean also the cup 120 with the cleaning solution at the cleaning step of the rear surface and the peripheral end surface at Step S1e. In other words, the cleaning step of the rear surface and the peripheral end surface at Step S1e can also serve as the cleaning step of the cup 120. This can improve the throughput of the protective film forming sequence including the cleaning of the cup 120 and reduce the consumption of the cleaning solution.

<Another Example of the Discharge Time of the Protective Liquid from the Front-Surface Side Coating Nozzle 132>

In the above example, the discharge time of the protective liquid from the front-surface side coating nozzle 132 at Step S1c is set constant irrespective of the formation width of the protective film, namely, irrespective of the coating width of the protective liquid from the front-surface side coating nozzle 132 to the wafer W.

In place of the above, the discharge time of the protective liquid may be changed and set depending on the coating width of the protective liquid from the front-surface side coating nozzle 132 to the wafer W. This change is performed by the control device 5, for example, based on correlation data between the coating width and the discharge time acquired and stored in advance in the storage and the set coating width.

This can decrease the time during which the protective liquid from the front-surface side coating nozzle 132 is supplied outside the peripheral edge portion of the wafer W, and thus can prevent the protective liquid from adhering to the mountain-shaped guide part 121.

### <Another Example of the Numbers of Arrangement and the Positions of the Rear-Surface Side Coating Nozzles 151 and the Cleaning Nozzles 141>

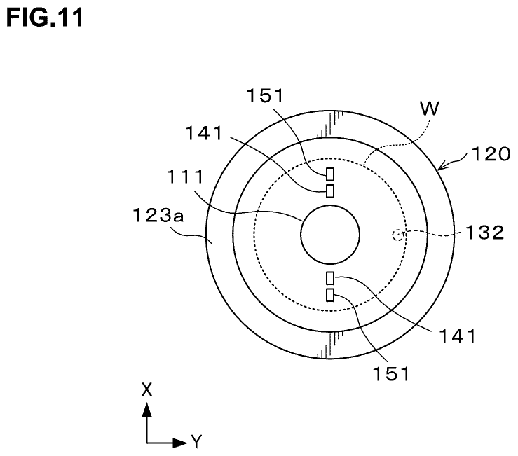

FIG. 11 is a view illustrating another example of the numbers of arrangement and the positions of the rear-surface side coating nozzles 151 and the cleaning nozzles 141.

As illustrated in FIG. 11, a plurality of (two in the example of the drawing) rear-surface side coating nozzles 151 may be provided. In the example of FIG. 11, the two rear-surface side coating nozzles 151 are provided at positions facing each other across the spin chuck 111 in a plan view.

Further, the rear-surface side coating nozzle 151 may be provided upstream from the supply position of the protective liquid from the front-surface side coating nozzle 132 in the rotation direction of the wafer W. This can prevent the rear-surface side coating nozzle 151 from being contaminated with the protective liquid from the front-surface side coating nozzle 132.

Note that the rear-surface side coating nozzle 151 located downstream from the supply position of the protective liquid from the front-surface side coating nozzle 132 in the rotation direction of the wafer W may be provided at a position displaced by 90° or more in the rotation direction of the wafer W from the supply position of the protective liquid from the front-surface side coating nozzle 132. This can also prevent the rear-surface side coating nozzle 151 from being contaminated with the protective liquid from the front-surface side coating nozzle 132.

As with the rear-surface side coating nozzles 151, a plurality of cleaning nozzles 141 may be provided. Further, the cleaning nozzle 141 may also be provided upstream from the supply position of the protective liquid from the front-surface side coating nozzle 132 in the rotation direction of the wafer W. The cleaning nozzle 141 located downstream from the supply position of the protective liquid from the front-surface side coating nozzle 132 in the rotation direction of the wafer W may be provided at a position displaced by 90° or more in the rotation direction of the wafer W from the supply position of the protective liquid from the front-surface side coating nozzle 132.

### <Another Example of the Rear-Surface Side Coating Nozzle 151>

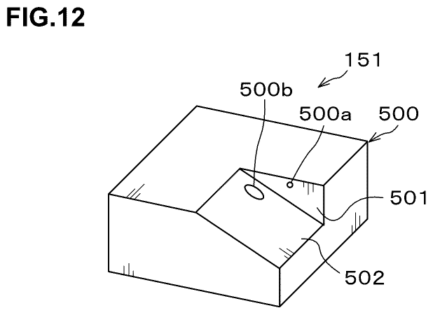

FIG. 12 to FIG. 14 are views illustrating other examples of the rear-surface side coating nozzle 151, respectively.

The rear-surface side coating nozzle 151 in FIG. 12 has a nozzle head 500, and the nozzle head 500 is provided with a protective liquid discharge port 500a and a solvent discharge port 500b.

The protective liquid discharge port 500a is an example of a coating solution discharge port which discharges the coating solution for forming the protective film, namely, the protective liquid.

The solvent discharge port 500b is provided separately from the protective liquid discharge port 500a and discharges a solvent. For the solvent, for example, the same treatment solution as the cleaning solution discharged from the cleaning nozzle 141 is used.

For example, the nozzle head 500 has a vertical surface 501, and the vertical surface 501 is formed with the protective liquid discharge port 500a. Further, the nozzle head 500 has a discharge surface 502 vertically extending from the vertical surface 501 in a discharge direction of the protective liquid from the protective liquid discharge port 500a, and the solvent discharge port 500b is formed at an upper portion of the discharge surface 502. The solvent discharge port 500b discharges the solvent toward the vertical surface 501. Specifically, the solvent discharge port 500b discharges the solvent toward a portion of the vertical surface 501 where the protective liquid discharge port 500a is formed, namely, the discharge angle of the solvent from the solvent discharge port 500b is set such that the solvent directly hits the protective liquid discharge port 500a. Therefore, it is possible to more surely clean the protective liquid discharge port 500a and its surroundings. Further, the solvent discharge port 500b is larger than the protective liquid discharge port 500a. Therefore, a large amount of the solvent can be discharged from the solvent discharge port 500b, so that it is possible to clean up the protective liquid discharge port 500a and its surroundings in a short time.

The solvent discharge port 500b is formed at a portion on the spin chuck 111 side, namely, the inside of the protective liquid discharge port 500a on the discharge surface 502. The discharge surface 502 may be inclined downward from the inside to the outside. This can make the solvent or the like which is discharged from the solvent discharge port 500b, hits the vertical surface 501, and then reaches the discharge surface 502, flow downward on the outside along the discharge surface 502 and be drained from the top of the nozzle head 500.

The protective liquid discharge port 500a is connected to the above supply mechanism 133 for the protective liquid via a flow path (not illustrated) for the protective liquid provided in the nozzle head 500.

Further, the solvent discharge port 500b is connected to a supply mechanism (not illustrated) for the solvent via a flow path (not illustrated) for the solvent provided in the nozzle head 500. The supply mechanism for the solvent has, for example, a supply pipe whose one end is connected to the supply source of the solvent. This supply pipe is provided with a supply equipment group for controlling the supply of the solvent from the supply source of the solvent. The supply equipment group has, for example, a supply valve for switching between the supply and supply stop of the solvent and a flow rate regulating valve for regulating the flow rate of the solvent. The supply equipment group of the supply mechanism for the solvent is controlled, for example, by the control device 5.

In the case of using the rear-surface side coating nozzle 151 in FIG. 12, a step of cleaning the protective liquid discharge port 500a with the solvent from the solvent discharge port 500b, specifically, a step of cleaning the protective liquid discharge port 500a with the solvent discharged from the solvent discharge port 500b toward the vertical surface 501 is performed. The cleaning step of the protective liquid discharge port 500a may perform a dummy-discharge of the protective liquid from the protective liquid discharge port 500a while performing the cleaning with the solvent discharged from the solvent discharge port 500b. This can remove a solidified protective liquid in the case where the protective liquid discharge port 500a is clogged due to solidification of the protective liquid, and prevent the solvent from entering the protective liquid discharge port 500a.

The cleaning step of the protective liquid discharge port 500a is performed after the wafer W which has been subjected to Step S1a to Step S1g of Step S1 is separated from the spin chuck 111. This is because if the solvent is discharged from the solvent discharge port 500b while the wafer W, which has the protective film formed on the rear surface of the wafer W, is mounted on the spin chuck 111, the solvent may come into contact with the protective film on the rear surface of the wafer W to form irregularities on the protective film. This is also because if the discharge of the protective liquid is also performed during the discharge of the solvent, the protective liquid newly comes into contact with the protective film on the rear surface of the wafer W to form irregularities or cause film thickness unevenness. In other words, by the above cleaning step of the protective liquid discharge port 500a in a state where the wafer W is separated from the spin chuck 111, namely, in a state where the wafer W is not located on the spin chuck 111, it is possible to prevent the occurrence of irregularities on the protective film on the rear surface of the wafer W due to the solvent or the protective liquid or the occurrence of the film thickness unevenness of the protective film on the rear surface of the wafer W.

The cleaning step of the protective liquid discharge port 500a is performed, specifically, after the wafer W which has been subjected to Step S1a to Step S1g of Step S1 is separated from the spin chuck 111 and before Step S1e (cleaning of the rear surface and the peripheral edge surface) of Step S1 for the next wafer W. Accordingly, after the wafer W which has been subjected to Step S1a to Step S1g of Step S1 is separated from the spin chuck 111, the cleaning step of the protective liquid discharge port 500a may be performed in parallel with Step S1c (protective liquid supply from the front surface side) of Step S1 on the next wafer W.

Further, the cleaning step of the protective liquid discharge port 500a in a state where the wafer W is separated from the spin chuck 111, namely, in a state where the wafer W is not located on the spin chuck 111 is performed, for example, every time n wafers W (n is an integer of one or more) are treated.

Further, before and after Step S1a to Step S1g of Step S1 are performed on the plurality of wafers W belonging to the same lot, the above cleaning step of the protective liquid discharge port 500a in a state where the wafer W is not located on the spin chuck 111 may be performed.

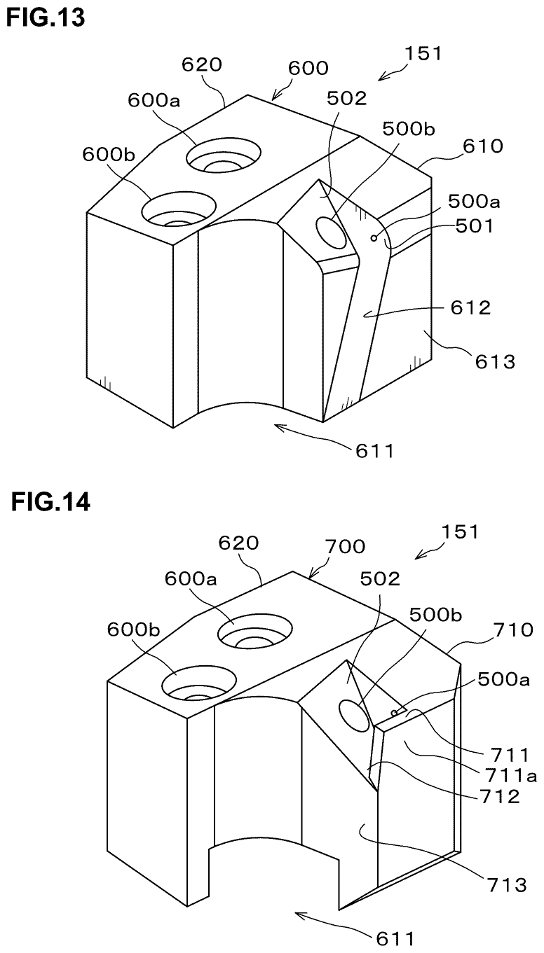

The rear-surface side coating nozzle 151 in FIG. 13 has a nozzle head 600. The protective liquid discharge port 500a and the solvent discharge port 500b are provided at a portion 610 on the opposite side to the spin chuck 111 side, namely, the outside of the nozzle head 600. Note that at a portion 620 on the spin chuck 111 side, namely, the inside of the nozzle head 600, a connection port 600a to which the supply pipe of the protective liquid is connected and a connection port 600b to which the supply pipe of the solvent is connected are provided.

The nozzle head 600 has a cutout 611 at a portion downstream in the protective liquid discharge direction from the protective liquid discharge port 500a in the portion 610 on the outside side. The protective liquid from the protective liquid discharge port 500a can reach the portion, but the solvent discharged from the solvent discharge port 500b (specifically, the solvent discharged from the solvent discharge port 500b and bounced from the vertical surface 501) is unlikely to reach the portion. Therefore, the protective liquid may remain at the portion. This can be prevented by the provision of the cutout 611.

Further, the nozzle head 600 has a surface 612 extending in the protective liquid discharge direction from below the protective liquid discharge port 500a is an inclined surface facing downward in the protective liquid discharge direction. Therefore, even if the protective liquid lands on the surface 612 when the discharge from the protective liquid discharge port 500a is stopped, the protective liquid can be guided along the surface 612 being the inclined surface to the outside of the nozzle head 600. Further, the solvent discharged from the solvent discharge port 500b and bounced from the vertical surface 501 can be made to flow along the surface 612. Accordingly, it is possible to prevent the protective liquid from remaining on the surface 612.

Further, the protective liquid reaching the lower surface of the nozzle head 600 via the surface 612 or the like can also be removed with the solvent similarly reaching the lower surface of the nozzle head 600 via the surface 612.

At the nozzle head 600, a part of the solvent discharged from the solvent discharge port 500b and reaching the vertical surface 501 is bounced from the vertical surface 501 as above and then flows along the surface 612, and another part thereof reaches the vertical surface 501 and then flows downward along an outer end surface 613 of the nozzle head 600. The protective liquid adhering to the lower surface of the nozzle head 600 can be removed also with the solvent flowing downward along the outer end surface 613 of the nozzle head 600.

Note that in the example of the drawing, the surface 612 extends in the protective liquid discharge direction from the lower end of the vertical surface 501 provided with the protective liquid discharge port 500a to the lower end of the nozzle head 600 and is formed by the above-explained inclined surface down to the outer end of the nozzle head 600.

The rear-surface side coating nozzle 151 in FIG. 14 has a nozzle head 700. The protective liquid discharge port 500a and the solvent discharge port 500b are provided at a portion 710 on the opposite side to the spin chuck 111 side, namely, the outside of the nozzle head 700.

The nozzle head 700 has the cutout 611 at a portion downstream in the protective liquid discharge direction from the protective liquid discharge port 500a in the portion 710 on the outside side, like the nozzle head 600 in FIG. 13.

The nozzle head 700 further has a wall part 711 extending, in a manner to face the solvent discharge port 500b, from a portion downstream from the protective liquid discharge port 500a, in the discharge direction of the solvent from the solvent discharge port 500b on the vertical surface 501 provided with the protective liquid discharge port 500a. Therefore, it is possible to dam up the solvent discharged from the solvent discharge port 500b and bounced from the vertical surface 501 by the wall part 711 and therefore to make the dammed up solvent flow in a protective liquid discharge direction to a portion 712 extending in the protective liquid discharge direction from below the protective liquid discharge port 500a. Accordingly, even if the protective liquid lands on the portion 712 when stopping the discharge from the protective liquid discharge port 500a, the protective liquid can be removed with the solvent.

Further, the protective liquid reaching the lower surface of the nozzle head 700 through the portion 712, a side surface 713 on the downstream side in the protective liquid discharge direction, and so on can also be removed with the solvent similarly reaching the lower surface of the nozzle head 700 through the portion 712 and the side surface 713.

At the nozzle head 700, a part of the solvent discharged from the solvent discharge port 500b and reaching the vertical surface 501 is dammed up by the wall part 711 and then flows along the portion 712, and another part thereof flows over the wall part 711 and flows downward along an outer side surface 711a of the wall part 711. The protective liquid adhering to the lower surface of the nozzle head 700 can also be removed with the solvent flowing downward along the outer side surface 711a of the wall part 711.

In the example of the drawing, the wall part 711 is formed in a manner to extend in the vertical direction from the outer end of the vertical surface 501 provided with the protective liquid discharge port 500a and extend upward in the vertical direction from the outer end of the discharge surface 502.

Besides, the above portion 712 may be composed of an inclined surface like the surface 612 of the nozzle head 600 in FIG. 13.

### Second Embodiment

### <Protective Film Forming Apparatus>

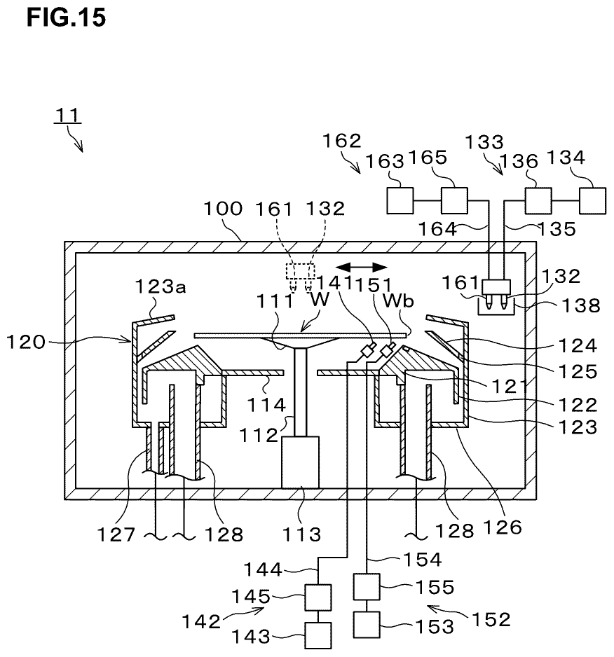

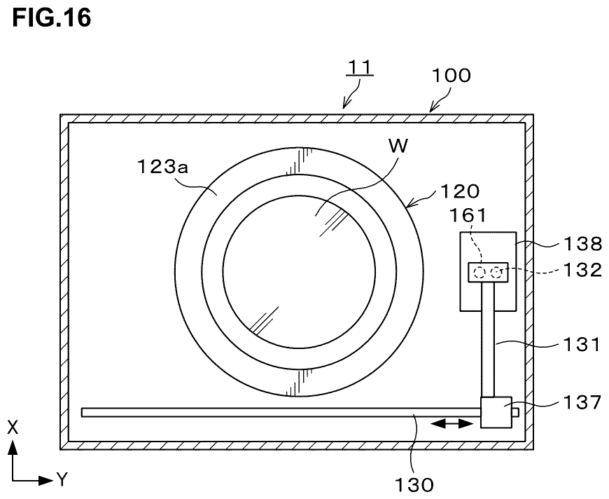

FIG. 15 is an explanatory view schematically illustrating from a side the outline of a configuration of a protective film forming apparatus according to a second embodiment, and FIG. 16 is an explanatory view schematically illustrating the outline from a plane.

In the protective film forming apparatus 11 in FIG. 15 and FIG. 16, a front-surface side cleaning nozzle 161 as a front-surface side cleaning solution supplier is supported on the arm 131 in addition to the front-surface side coating nozzle 132. The front-surface side cleaning solution supplier is configured to supply the cleaning solution from the front surface side of the wafer W held on the spin chuck 111, specifically, supply the cleaning solution outside the peripheral edge of the wafer from the front surface side of the wafer W.

The front-surface side cleaning nozzle 161 and the front-surface side coating nozzle 132 are provided in a manner to line up along a direction in which the front-surface side coating nozzle 132 moves, namely, an extending direction (Y-direction) of the rail 130.

The cleaning solutions supplied from the front-surface side cleaning nozzle 161 and the cleaning nozzle 141 are the same. The front-surface side cleaning nozzle 161 is connected to a supply mechanism 162 for the cleaning solution. The supply mechanism 162 has, for example, a supply pipe 164 whose one end is connected to a supply source 163 of the cleaning solution. The supply pipe 164 is provided with a supply equipment group 165 for controlling the supply of the cleaning solution from the supply source 163. The supply equipment group 165 has, for example, a supply valve for switching between the supply and supply stop of the cleaning solution and a flow rate regulating valve for regulating the flow rate of the cleaning solution.

The supply equipment group 165 is controlled, for example, by the control device 5.

Further, the discharge angle in a plan view of the front-surface side cleaning nozzle 161 is set to be the same as the discharge angle in a plan view of the front-surface side coating nozzle 132. Similarly, the discharge angle in a side view (depression angle) of the front-surface side cleaning nozzle 161 is set to be the same as the discharge angle in a side view of the front-surface side coating nozzle 132.

In the case of using the protective film forming apparatus 11 in FIG. 15 and FIG. 16, a step of cleaning the cup 120 to which the protective liquid adheres with the cleaning solution from the front-surface side cleaning nozzle 161 is performed. Specifically, at Step S1c (first protective film forming step), a step of cleaning the mountain-shaped guide part 121 to which the protective liquid supplied outside the peripheral edge of the wafer W from the front-surface side coating nozzle 132 with the cleaning solution from the front-surface side cleaning nozzle 161 is performed.

The cleaning step of the cup 120 (mountain-shaped guide part 121) is performed, for example, during the cleaning step on the rear surface and the peripheral end surface at Step S1e. Further, the cleaning step of the mountain-shaped guide part 121 may be performed during the protective film dry step at Step S1d.

At the cleaning step of the mountain-shaped guide part 121, specifically, for example, the front-surface side cleaning nozzle 161 is moved to the above-explained discharge start position Pb outside the peripheral edge of the wafer W, and then the discharge of the cleaning solution from the front-surface side cleaning nozzle 161 is performed for a predetermined time while the position of the front-surface side cleaning nozzle 161 is fixed at the discharge start position Pb. The front-surface side cleaning nozzle 161 in a state of having been moved to the discharge start position Pb may be partially overlapped with the wafer W in a plan view unless the cleaning solution from the nozzle 161 hits the wafer W held on the spin chuck 111.

Cleaning the mountain-shaped guide part 121 as above makes it possible to prevent the protective liquid adhering to the mountain-shaped guide part 121 from adversely affecting the treatment on the wafer in the protective film forming apparatus 11.

Further, setting the discharge angle in a plan view and the discharge angle in a side view of the front-surface side cleaning nozzle 161 the same as those of the front-surface side coating nozzle 132 makes it possible to more surely remove the protective liquid discharged from the front-surface side coating nozzle 132 and adhering to the mountain-shaped guide part 121 with the cleaning solution from the front-surface side cleaning nozzle 161.

### Modifications

Though the protective film forming apparatus 11 is provided in the coating system 2 different from the coating and developing apparatus to which the exposure apparatus is connected in the above examples, the protective film forming apparatus 11 may be provided in the coating and developing apparatus. In other words, the protective film forming apparatus 11 provided in the coating and developing apparatus may form the protective film at the peripheral edge portion of the wafer W as explained above.

The embodiments disclosed herein are examples in all respects and should not be considered to be restrictive. Various omissions, substitutions, and changes may be made in the embodiments without departing from the scope and spirit of the attached claims. For example, configuration requirements of the above embodiments can be arbitrarily combined. The operations and effects about the configuration requirements relating to an arbitrary combination can be obtained as a matter of course from the combination, and those skilled in the art can obtain clear other operations and other effects from the description herein.

Besides, the effects explained herein are merely explanatory or illustrative in all respects and not restrictive. The technique relating to this disclosure can offer other clear effects to those skilled in the art from the description herein in addition to or in place of the above effects.

Note that the following configurations also belong to the technical scope of this disclosure.
(1) A method for forming a protective film at a peripheral edge portion of a substrate having a plurality of patterning layers on a front surface, the method including:
   (A) supplying a coating solution for forming the protective film to the front surface of the substrate from a front-surface side coater located on the front surface side of the substrate while rotating the substrate to form the protective film at the peripheral edge portion of the substrate;
   (B), after the (A), supplying a cleaning solution to a rear surface of the substrate from a cleaning solution supplier located on the rear surface side of the substrate while rotating the substrate to clean the rear surface and a peripheral end surface of the substrate; and
   (C), after the (B), supplying the coating solution to the rear surface of the substrate from a rear-surface side coater located on the rear surface side of the substrate while rotating the substrate to form the protective film on the rear surface and the peripheral end surface of the peripheral edge portion of the substrate.
(2) The protective film forming method according to the (1), wherein
   a position where the cleaning solution supplier supplies the cleaning solution at the (B) on the rear surface of the substrate is inside a position where the rear-surface side coater supplies the coating solution at the (C) on the rear surface of the substrate.
(3) The protective film forming method according to the (1) or (2), wherein
   a number of rotations of the substrate at the (A), a number of rotations at the (C), and a number of rotations at the (B) are lower in this order.
(4) The protective film forming method according to any one of the (1) to (3), wherein
   the (A) moves the front-surface side coater from outside a peripheral edge of the substrate to above the peripheral edge portion of the substrate and moves the front-surface side coater from above the peripheral edge portion of the substrate to outside the peripheral edge of the substrate at the supply of the coating solution.
(5) The protective film forming method according to any one of the (1) to (4), further including
   (D), after the (A) and before the (B), rotating the substrate with the coating solution not being supplied to the substrate to dry the protective film, wherein a number of rotations of the substrate at the (D) is increased in stages.
(6) The protective film forming method according to any one of the (1) to (5), wherein
   during the (D), the cleaning solution is supplied to outside the peripheral edge of the substrate from a front-surface side cleaning solution supplier located on the front surface side of the substrate to clean a cup configured to receive a treatment solution dropped from the substrate.
(7) The protective film forming method according to any one of the (1) to (6), wherein
   during the (B), the cleaning solution is supplied to outside the peripheral edge of the substrate from the front-surface side cleaning solution supplier located on the front surface side of the substrate to clean the cup configured to receive the treatment solution dropped from the substrate.
(8) The protective film forming method according to the (6) or (7), wherein
   a discharge direction in a plan view and a discharge direction in a side view of the cleaning solution from the front-surface side cleaning solution supplier are same as a discharge direction in a plan view and a discharge direction in a side view of the coating solution from the front-surface side coater, respectively.
(9) The protective film forming method according to any one of the (1) to (8), wherein
   an angle formed between a rotation direction of the substrate at a landing point of the coating solution from the front-surface side coater onto the substrate and a discharge direction in a plan view of the coating solution from the front-surface side coater is an acute angle.
(10) The protective film forming method according to any one of the (1) to (9), further including
   (E), before the (A), supplying the cleaning solution to the rear surface of the substrate from the cleaning solution supplier located on the rear surface side of the substrate while rotating the substrate to clean a cup surrounding a periphery of the substrate.
(11) The protective film forming method according to any one of the (1) to (10), further including
   (F) cleaning a coating solution discharge port configured to discharge the coating solution of the rear-surface side coater, with a solvent from a solvent discharge port provided separately from the coating solution discharge port at the rear-surface side coater.
(12) The protective film forming method according to the (11), wherein
   the (F) is performed after the substrate subjected to the (A) to the (C) is separated from a rotary holder configured to rotatably hold the substrate.
(13) The protective film forming method according to the (11) or (12), wherein
   the (F) cleans the coating solution discharge port with the solvent while discharging the coating solution from the coating solution discharge port of the rear-surface side coater.
(14) The protective film forming method according to any one of the (11) to (13), wherein
   the (F) discharges the solvent from the solvent discharge port toward a wall surface provided with the coating solution discharge port of the rear-surface side coater.
(15) The protective film forming method according to any one of the (11) to (14), wherein
   before and after the (A) to the (C) are performed on a plurality of substrates belonging to a same lot, the (F) is performed.
(16) The protective film forming method according to any one of the (1) to (15), further including
   changing a discharge time of the coating solution from the front-surface side coater at the (A) based on correlation data acquired in advance between a coating width of the coating solution from the front-surface side coater to the substrate and the discharge time and on a set coating width.
(17) The protective film forming method according to any one of the (1) to (16), wherein
   the protective film is a protective film against a cleaning solution for removing a layer made of a same kind of material as a base of the substrate on the substrate by a batch treatment.
(18) A protective film forming apparatus for forming a protective film at a peripheral edge portion of a substrate having a plurality of patterning layers on a front surface, the protective film forming apparatus including:
   a rotary holder configured to hold and rotate the substrate;
   a front-surface side coater configured to supply a coating solution for forming the protective film to the front surface of the substrate from the front surface side of the substrate;
   a cleaning solution supplier configured to supply a cleaning solution to a rear surface of the substrate from the rear surface side of the substrate;
   a rear-surface side coater configured to supply the coating solution to the rear surface of the substrate from the rear surface side of the substrate; and
   a controller, wherein
   the controller is configured to execute:
   (A) supplying the coating solution to the front surface of the substrate from the front-surface side coater while rotating the substrate to form the protective film at the peripheral edge portion of the substrate;
   (B), after the (A), supplying the cleaning solution to the rear surface of the substrate from the cleaning solution supplier while rotating the substrate to clean the rear surface and a peripheral end surface of the substrate; and
   (C), after the (B), supplying the coating solution to the rear surface of the substrate from the rear-surface side coater while rotating the substrate to form the protective film on the rear surface and the peripheral end surface of the peripheral edge portion of the substrate.
(19) The protective film forming apparatus according to the (18), wherein
   a position where the cleaning solution supplier supplies the cleaning solution at the (B) on the rear surface of the substrate is inside a position where the rear-surface side coater supplies the coating solution at the (C) on the rear surface of the substrate.
(20) The protective film forming apparatus according to the (18) or (19), wherein
   the controller is configured to further execute (D), after the (A) and before the (B), rotating the substrate with the coating solution not being supplied to the substrate to dry the protective film, wherein
   a number of rotations of the substrate at the (D) is increased in stages.
(21) The protective film forming apparatus according to any one of the (18) to (20), wherein
   an angle formed between a rotation direction of the substrate at a landing point of the coating solution from the front-surface side coater onto the substrate and a discharge direction in a plan view of the coating solution from the front-surface side coater is an acute angle.
(22) The protective film forming apparatus according to any one of the (18) to (21), further including
   a cup provided to be capable of surrounding the substrate held on the rotary holder, wherein
   the controller is configured to further execute (E), before the (A), supplying the cleaning solution to the rear surface of the substrate from the cleaning solution supplier located on the rear surface side of the substrate while rotating the substrate to clean the cup.
(23) The protective film forming apparatus according to any one of the (18) to (22), wherein:
   the rear-surface side coater includes:
      a coating solution discharge port configured to discharge the coating solution; and
      a solvent discharge port provided separately from the coating solution discharge port and configured to discharge a solvent; and
   the controller is configured to further execute (F) cleaning the coating solution discharge port with the solvent from the solvent discharge port.
(24) The protective film forming apparatus according to the (23), wherein
   a cutout is provided at a portion on the coating solution discharge port side of the rear-surface side coater that is a portion downstream in a discharge direction of the coating solution from the coating solution discharge port.
(25) The protective film forming apparatus according to the (23) or (24), wherein
   a surface extending in a discharge direction of the coating solution from below the coating solution discharge port of the rear-surface side coater is an inclined surface facing downward in the discharge direction.
(26) The protective film forming apparatus according to any one of the (23) to (25), wherein
   the rear-surface side coater has a wall part extending, in a manner to face the solvent discharge port, from a portion downstream from the coating solution discharge port, in a discharge direction of the solvent from the solvent discharge port on a surface provided with the coating solution discharge port.
(27) A substrate treatment system including:
   a coating system including the protective film forming apparatus according to any one of the (18) to (25);
   a cleaning system including a cleaning apparatus configured to remove a layer made of a same kind of material as a base of the substrate on which the protective film is formed, with a cleaning solution by a batch treatment; and
   a removing system including a removing apparatus configured to remove the protective film from the substrate.

According to this disclosure, it is possible to appropriately form a protective film at a peripheral edge portion of a substrate having a plurality of patterning layers on a front surface.

What is claimed is:

1. A method for forming a protective film at a peripheral edge portion of a substrate having a plurality of patterning layers on a front surface, the method comprising:
(A) supplying a coating solution for forming the protective film to the front surface of the substrate from a front-surface side coater located on the front surface side of the substrate while rotating the substrate to form the protective film at the peripheral edge portion of the substrate;
(B), after the (A), supplying a cleaning solution to a rear surface of the substrate from a cleaning solution supplier located on the rear surface side of the substrate while rotating the substrate to clean the rear surface and a peripheral end surface of the substrate; and
(C), after the (B), supplying the coating solution to the rear surface of the substrate from a rear-surface side coater located on the rear surface side of the substrate while rotating the substrate to form the protective film on the rear surface and the peripheral end surface of the peripheral edge portion of the substrate.

2. The protective film forming method according to claim 1, wherein
a position where the cleaning solution supplier supplies the cleaning solution at the (B) on the rear surface of the substrate is inside a position where the rear-surface side coater supplies the coating solution at the (C) on the rear surface of the substrate.

3. The protective film forming method according to claim 1, wherein
a number of rotations of the substrate at the (A), a number of rotations at the (C), and a number of rotations at the (B) are lower in this order.

4. The protective film forming method according to claim 1, wherein
the (A) moves the front-surface side coater from outside a peripheral edge of the substrate to above the peripheral edge portion of the substrate and moves the front-surface side coater from above the peripheral edge portion of the substrate to outside the peripheral edge of the substrate at the supply of the coating solution.

5. The protective film forming method according to claim 1, further comprising
(D), after the (A) and before the (B), rotating the substrate with the coating solution not being supplied to the substrate to dry the protective film, wherein
a number of rotations of the substrate at the (D) is increased in stages.

6. The protective film forming method according to claim 5, wherein
during the (B) or during the (D), the cleaning solution is supplied to outside the peripheral edge of the substrate from a front-surface side cleaning solution supplier located on the front surface side of the substrate to clean a cup configured to receive a treatment solution dropped from the substrate.

7. The protective film forming method according to claim 6, wherein
a discharge direction in a plan view and a discharge direction in a side view of the cleaning solution from the front-surface side cleaning solution supplier are same as a discharge direction in a plan view and a discharge direction in a side view of the coating solution from the front-surface side coater, respectively.

8. The protective film forming method according to claim 1, wherein
an angle formed between a rotation direction of the substrate at a landing point of the coating solution from the front-surface side coater onto the substrate and a discharge direction in a plan view of the coating solution from the front-surface side coater is an acute angle.

9. The protective film forming method according to claim 1, further comprising
(F) cleaning a coating solution discharge port configured to discharge the coating solution of the rear-surface side coater, with a solvent from a solvent discharge port provided separately from the coating solution discharge port at the rear-surface side coater.

10. The protective film forming method according to claim 9, wherein
the (F) cleans the coating solution discharge port with the solvent while discharging the coating solution from the coating solution discharge port of the rear-surface side coater.

11. The protective film forming method according to claim 9, wherein
the (F) discharges the solvent from the solvent discharge port toward a wall surface provided with the coating solution discharge port of the rear-surface side coater.

12. The protective film forming method according to claim 1, further comprising
changing a discharge time of the coating solution from the front-surface side coater at the (A) based on correlation data acquired in advance between a coating width of the coating solution from the front-surface side coater to the substrate and the discharge time and on a set coating width.

13. A protective film forming apparatus for forming a protective film at a peripheral edge portion of a substrate having a plurality of patterning layers on a front surface, the protective film forming apparatus comprising:
a rotary holder configured to hold and rotate the substrate;
a front-surface side coater configured to supply a coating solution for forming the protective film to the front surface of the substrate from the front surface side of the substrate;
a cleaning solution supplier configured to supply a cleaning solution to a rear surface of the substrate from the rear surface side of the substrate;
a rear-surface side coater configured to supply the coating solution to the rear surface of the substrate from the rear surface side of the substrate; and
a controller, wherein
the controller is configured to execute:
(A) supplying the coating solution to the front surface of the substrate from the front-surface side coater while rotating the substrate to form the protective film at the peripheral edge portion of the substrate;
(B), after the (A), supplying the cleaning solution to the rear surface of the substrate from the cleaning solution supplier while rotating the substrate to clean the rear surface and a peripheral end surface of the substrate; and
(C), after the (B), supplying the coating solution to the rear surface of the substrate from the rear-surface side coater while rotating the substrate to form the protective film on the rear surface and the peripheral end surface of the peripheral edge portion of the substrate.

14. The protective film forming apparatus according to claim 13, wherein
a position where the cleaning solution supplier supplies the cleaning solution at the (B) on the rear surface of the substrate is inside a position where the rear-surface side coater supplies the coating solution at the (C) on the rear surface of the substrate.

15. The protective film forming apparatus according to claim 13, wherein
the controller is configured to further execute (D), after the (A) and before the (B), rotating the substrate with the coating solution not being supplied to the substrate to dry the protective film, wherein
a number of rotations of the substrate at the (D) is increased in stages.

16. The protective film forming apparatus according to claim 13, wherein:
the rear-surface side coater comprises:
a coating solution discharge port configured to discharge the coating solution; and
a solvent discharge port provided separately from the coating solution discharge port and configured to discharge a solvent; and
the controller is configured to further execute (F) cleaning the coating solution discharge port with the solvent from the solvent discharge port.

17. The protective film forming apparatus according to claim 16, wherein
a cutout is provided at a portion on the coating solution discharge port side of the rear-surface side coater that is a portion downstream in a discharge direction of the coating solution from the coating solution discharge port.

18. The protective film forming apparatus according to claim 16, wherein
a surface extending in a discharge direction of the coating solution from below the coating solution discharge port of the rear-surface side coater is an inclined surface facing downward in the discharge direction.

19. The protective film forming apparatus according to claim 16, wherein
the rear-surface side coater has a wall part extending, in a manner to face the solvent discharge port, from a portion downstream from the coating solution discharge port, in a discharge direction of the solvent from the solvent discharge port on a surface provided with the coating solution discharge port.

20. A substrate treatment system comprising:
a coating system comprising the protective film forming apparatus according to claim 13;
a cleaning system comprising a cleaning apparatus configured to remove a layer made of a same kind of material as a base of the substrate on which the protective film is formed, with a cleaning solution by a batch treatment; and
a removing system comprising a removing apparatus configured to remove the protective film from the substrate.
